(19) United States
(12) Patent Application Publication
(10) Pub. No.: US 2007/0085165 A1
(43) Pub. Date: Apr. 19, 2007

(54) Capacitor, semiconductor device including the capacitor and methods of fabricating the same

(75) Inventors: Han-Su Oh, Yongin-si (KR); Joo-Hyun Jeong, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/582,388

(22) Filed: Oct. 18, 2006

(30) Foreign Application Priority Data
Oct. 19, 2005 (KR) 10-2005-0098834

(51) Int. Cl. H01L 29/00

(52) U.S. Cl. 257/532

(57) ABSTRACT

A capacitor, a semiconductor device and methods of fabricating the same are disclosed. The capacitor may include a lower electrode, a dielectric layer covering an upper surface of the lower electrode and having a width wider than that of the lower electrode and an upper electrode covering an upper surface and sides of the dielectric layer. The semiconductor device may include a lower insulating layer on a lower line, the capacitor according to example embodiments, the lower electrode on the lower insulating layer and an upper insulating layer on the lower insulating layer and encompassing the capacitor.

### PRIORITY STATEMENT

This application claims priority under 35 USC § 119 to Korean Patent Application No. 10-2005-0098834, filed on Oct. 19, 2005, in the Korean Intellectual Property Office (KIPO), the entire contents of which are incorporated herein by reference.

### BACKGROUND

1. Field

Example embodiments relate to a capacitor, a semiconductor device including the capacitor and methods of fabricating the same. Other example embodiments relate to a metal insulator metal (MIM) capacitor, a semiconductor device including a metal insulator metal (MIM) capacitor and methods of fabricating the same.

2. Description of the Prior Art

A capacitor may be classified into a metal-oxide-silicon (MOS) capacitor, a PN junction capacitor, a polysilicon-insulator-polysilicon (PIP) capacitor and/or an MIM capacitor depending on its junction structure. The other capacitors excluding the MIM capacitor may use at least monosilicon and/or polysilicon as an electrode material. The monosilicon and/or the polysilicon may be limited in decreasing the resistance of a capacitor electrode due to its physical properties. If a bias voltage is applied to a monosilicon and/or polysilicon electrode, a depletion region may be generated, and the voltage may become unstable, so that a capacitance value may not remain uniform.

The MIM capacitor has been used for various analog products, mixed mode signal application products and/or system on chip (SoC) application products, wherein the MIM capacitor may reduce the resistance of a capacitor electrode to reduce its frequency dependency and its capacitance may not vary depending on voltage and temperature. For example, the MIM capacitor may be applied to an analog capacitor and/or a filter used for an analog or mixed mode signal application of wire and wireless communications, an RF capacitor of a relatively high frequency circuit, a capacitor of an image sensor and/or an LCD driver IC (LDI).

Attempts to obtain a thin MIM capacitor while using a relatively high dielectric material for relatively high density capacitance have been made. Due to the thin dielectric layer, leakage current may occur between upper and lower electrodes of the capacitor, thereby degrading the characteristics of a semiconductor device. This may be caused by the attachment of conductive etching byproducts to sides of the dielectric layer due to the thin dielectric layer and/or damage to the dielectric layer during an etching process.

### SUMMARY

Example embodiments provide a capacitor, a semiconductor device having improved reliability including the capacitor for reducing or minimizing the leakage of current between upper and lower electrodes. Example embodiments also provide methods of fabricating the above capacitor and semiconductor device.

According to example embodiments, a capacitor may include a lower electrode, a dielectric layer covering an upper surface of the lower electrode and having a width wider than that of the lower electrode and at least one upper electrode covering an upper surface and sides of the dielectric layer. The capacitor may further include an upper line made of the same conductive layer as that of the at least one upper electrode and an insulating spacer on the sides of the lower electrode. The at least one upper electrode may include a first upper electrode on the dielectric layer and aligned in a side profile of the dielectric layer, and a second upper electrode on the first upper electrode to adjoin the first upper electrode and to encompass sides of the first upper electrode and the dielectric layer. The upper line may be formed of the same conductive layer as that of the second upper electrode.

According to example embodiments, a semiconductor device may include a lower insulating layer on a lower line, the capacitor according to example embodiments, the lower electrode on the lower insulating layer and an upper insulating layer formed on the lower insulating layer and encompassing the capacitor. The upper insulating layer may encompass the dielectric layer and the at least one upper electrode. The dielectric layer may cover the upper surface and sides of the lower electrode. The dielectric layer may extend to the lower insulating layer to cover the sides of the lower electrode and adjoin the lower insulating layer. A lower end of the at least one upper electrode may partially adjoin the lower insulating layer. The lower insulating layer may include a via connected to the lower electrode and/or the lower line. The lower electrode may be formed of the same conductive layer as that of the via in the lower insulating layer.

In other example embodiments, a method of fabricating a capacitor may include providing a lower electrode, forming a dielectric layer covering an upper surface of the lower electrode and having a width wider than that of the lower electrode and forming at least one upper electrode covering an upper surface and sides of the dielectric layer.

According to example embodiments, a method of fabricating a semiconductor device may include forming a lower insulating layer on a lower line, forming the capacitor according to example embodiments and forming an upper insulating layer on the lower insulating layer before or after forming the at least one upper electrode, the upper insulating layer encompassing the capacitor.

### BRIEF DESCRIPTION OF THE DRAWINGS

Example embodiments will be more clearly understood from the following detailed description taken in conjunction with the accompanying drawings. FIGS. 1-7F represent non-limiting, example embodiments as described herein.

FIGS. 1-4 are diagrams illustrating a semiconductor device according to example embodiments;

FIGS. 5A to 5E are diagrams sequentially illustrating a method of fabricating a semiconductor device shown in FIG. 1;

FIGS. 6A to 6C are diagrams sequentially illustrating a method of fabricating a semiconductor device shown in FIG. 3; and

FIGS. 7A to 7E are diagrams sequentially illustrating a method of fabricating a semiconductor device shown in FIG. 4.

### DETAILED DESCRIPTION OF EXAMPLE EMBODIMENTS

Hereinafter, example embodiments will be described in detail with reference to the accompanying drawings. Example embodiments will be apparent by referring to the embodiments to be described in detail with reference to the accompanying drawings. However, example embodiments are not limited to the embodiments disclosed hereinafter, but may be implemented in diverse forms. The matters defined in the description are nothing but specific details provided to assist those of ordinary skill in the art in a comprehensive understanding of example embodiments, and example embodiments are only defined within the scope of the appended claims. In the entire description of example embodiments, the same drawing reference numerals are used for the same elements across various figures.

Also, the embodiments herein will be described with reference to diagrams. Modifications may be made in the exemplary views in accordance with the fabricating technologies and/or allowable errors. Example embodiments are not limited to specific forms as shown, but include modifications of forms produced by the fabricating process. For example, a right-angled etching region may be rounded or may have a predetermined or given curvature. Regions exemplarily shown in the drawings have rough properties and their shapes are not to be construed as limiting the scope of example embodiments. It may be understood that respective elements may be shown in the drawings in an enlarged or reduced size for convenience of description.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

Spatially relative terms, such as “beneath,” “below.” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements and/or components, but do not preclude the presence or addition of one or more other features, integers, steps, operations, elements, components and/or groups thereof.

Example embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

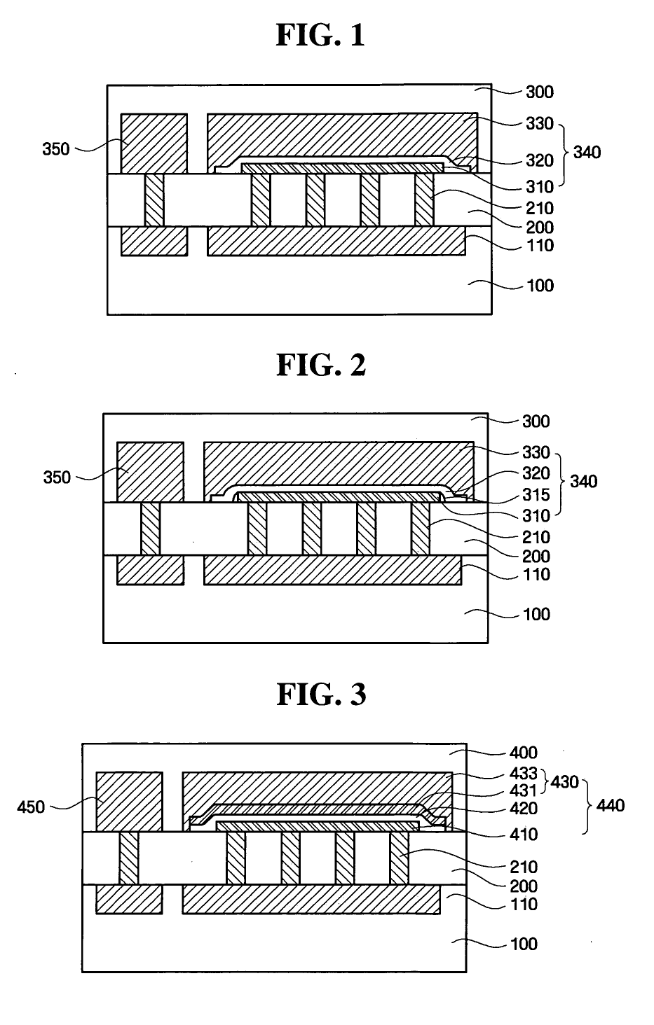

Hereinafter, a semiconductor device according to example embodiments will be described with reference to FIG. 1. FIG. 1 is a diagram illustrating a semiconductor device according to example embodiments. Referring to FIG. 1, the semiconductor device according to example embodiments may include a lower insulating layer 200, a capacitor 340 formed on the lower insulating layer 200, and an upper insulating layer 300. The lower insulating layer 200 may be formed on a lower line 110. The lower line 110 may be formed in another interlayer insulating layer 100 as shown in FIG. 1 but may not be limited to such structure. The lower line 110 may be formed in the lower insulating layer 200. The lower insulating layer may include vias 210 to electrically connect the lower line 110 with the capacitor 340. The capacitor 340 formed on the lower insulating layer 200 may include a lower electrode 310, a dielectric layer 320, and an upper electrode 330.

The lower electrode 310 may be formed on the lower insulating layer 200. The lower electrode 310 may be relatively thin and may reduce hillock. For example, the lower electrode 310 may be formed with a thickness of about 500 Å to about 1500 Å, and may be formed of a single layer of Ti, TiN, TiW, Ta, TaN, W, WN, Pt, Ir, Ru, Rh, Os, Pd, Al and/or Cu and/or a deposition layer of these materials. However, the lower electrode 310 may not be limited to the above structure. The dielectric layer 320 formed on the lower electrode 310 may cover an upper surface of the lower electrode 310 and may be wider than the lower electrode 310. The dielectric layer 320 may be formed to cover sides of the lower electrode 310 in addition to the upper surface of the lower electrode 310. The dielectric layer 320 may extend onto the lower insulating layer 200 to adjoin the lower insulating layer 200. The dielectric layer 320 may reduce or minimize the probability of contact between the lower electrode 310 and the lower insulating layer 200, thereby reducing or minimizing leakage current that may occur between the lower electrode 310 and the lower insulating layer 200.

The thickness and material of the dielectric layer 320 may be controlled depending on required physical properties and characteristics. For example, the dielectric layer 320 may be formed of a single layer of a SiO₂ layer, SiₓN_{y} layer, SiₓC_{y} layer, SiₓO_{y}N_{z} layer, SiₓO_{y}C_{z} layer, AlₓO_{y} layer, HfₓO_{y} layer, TaₓO_{y} layer and/or a relatively high dielectric ratio layer (high k) and/or a deposition layer of these materials. The dielectric layer 320 may be formed with a thickness of about 200 Å to about 1,500 Å. An upper electrode 330 may be formed on the dielectric layer 320 to cover an upper surface of the dielectric layer 320 and its side. The upper electrode 330 may extend in a predetermined or given width from the side of the dielectric layer 320. The upper electrode 330 of the capacitor 340 may be formed to have a width wider than that of the lower electrode 310, and a lower end of the upper electrode 330 may be in contact with the lower insulating layer 200.

The thickness and material of the upper electrode 330 may be controlled properly depending on the characteristics of the semiconductor device. For example, the upper electrode 330 may be formed of a single layer of Ti, TiN, TiW, Ta, TaN, W, WN, Pt, Ir, Ru, Rh, Os, Pd, Al and/or Cu and/or a deposition layer of these materials with a thickness of about 1,000 Å to about 40,000 Å. The upper electrode 330 may not be limited to the above materials and/or thickness. The capacitor 340, which may include the lower electrode 310, the dielectric layer 320 and the upper electrode 330, may be formed in the upper insulating layer 300 formed on the lower insulating layer 200. An upper line 350 made of the same conductive layer as that of the upper electrode 330 may be formed in the upper insulating layer 300. The upper electrode 330 may be provided with a line structure for routing in the upper insulating layer, whereby the process may be simplified and resistance of the capacitor may be reduced. Although the upper insulating layer 300 may be formed to cover the upper line 350 and the upper surface of the upper electrode 330 as shown in FIG. 1, the upper insulating layer 300 may be formed substantially to be even with the upper line 350 and the upper surface of the upper electrode 330.

Referring to FIG. 2, according to example embodiments, to reduce or prevent degradation to the reliability of the device from the thin dielectric layer 320 on a corner of the lower electrode 310, an insulating spacer 315 may additionally be formed on both sides of the lower electrode 310, and the dielectric layer 320 may be formed on the insulating spacer 315. Because the semiconductor device shown in FIG. 2 is substantially the same as that shown in FIG. 1 and the same reference numerals represent the same elements, its description will be omitted.

Hereinafter, a semiconductor device according to example embodiments will be described with reference to FIG. 3. Referring to FIG. 3, the semiconductor device according to example embodiments may include a capacitor 440, which may include a lower electrode 410, a dielectric layer 420, and an upper electrode 430. The upper electrode 430 may include a first upper electrode 431 and a second upper electrode 433. The first upper electrode 431 may be aligned in a side profile of the dielectric layer 420 formed on the lower electrode 410, and the second upper electrode 433 may be formed to cover an upper surface of the first upper electrode 431 and sides of the first upper electrode 431 and the dielectric layer 420. The first upper electrode 431 may serve to reduce or prevent the dielectric layer 420 from being damaged during the process of fabricating the semiconductor device (e.g., an etching process), thereby maintaining reliability of the semiconductor device.

The first upper electrode 431 and the second upper electrode 433 may be formed of the same material or different materials. For example, each of the upper electrodes 431 and 433 may be formed of a single layer of Ti, TiN, TiW, Ta, TaN, W, WN, Pt, Ir, Ru, Rh, Os, Pd, Al and/or Cu and/or a deposition layer of these materials. Each of the upper electrodes 431 and 433 may not be limited to such materials. The thickness of each upper electrode may be controlled depending on the semiconductor device. For example, the first upper electrode 431 may have a thickness of about 500 Å to about 1,500 Å while the second upper electrode 433 may have a thickness of about 1,000 Å to about 40,000 Å. Although not shown, an insulating spacer may additionally be formed on sides of the lower electrode 410 in the same manner as FIG. 2. Because the other elements except for the upper electrode 430 are substantially the same as those shown in FIG. 1, their description will be omitted. A reference numeral 400 may denote an upper insulating layer and a reference numeral 450 may denote an upper line.

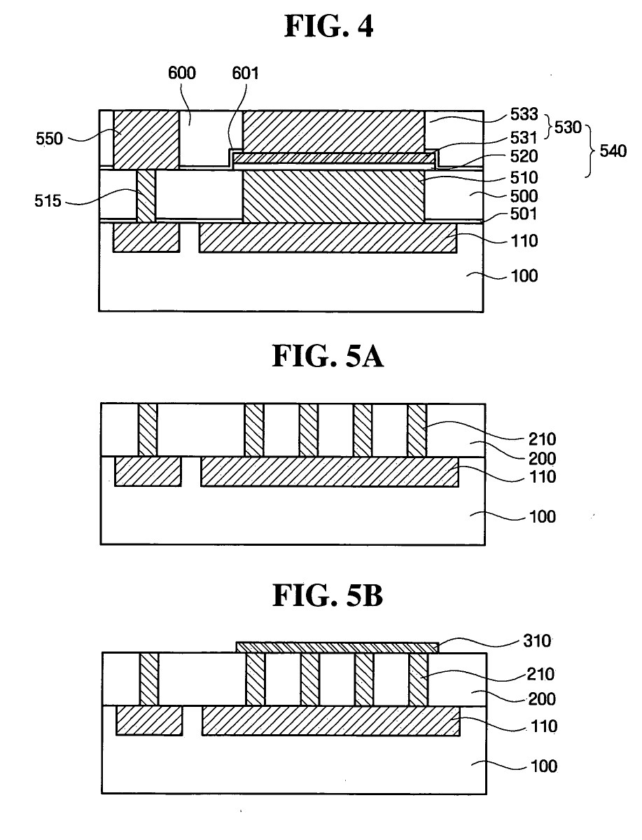

Hereinafter, a semiconductor device according to example embodiments will be described with reference to FIG. 4. Among elements of the semiconductor device shown in FIG. 4, elements substantially the same as those of FIG. 1 to FIG. 3 will be omitted or will be described in brief. Referring to FIG. 4, the semiconductor device according to example embodiments may include a lower insulating layer 500, a via 515 formed in the lower insulating layer 500, a capacitor 540, and an upper insulating layer 600. The lower insulating layer 500 may be formed on the lower line 110, and may include the via 515 connected with the lower line 110.

A lower electrode 510 of the capacitor 540 may be formed in the lower insulating layer 500 and be made of the same conductive layer as that of the via 210. For example, the lower electrode may be formed of a single layer of Ti, TiN, TiW, Ta, TaN, W, WN, Pt, Ir, Ru, Rh, Os, Pd, Al and/or Cu and/or a deposition layer of these materials. The thickness of the lower electrode 510 may be controlled depending on the semiconductor device. For example, the lower electrode 510 may have a thickness of about 2,000 Å to about 5,000 Å. A dielectric layer 520 may be formed on the lower electrode 510 to cover the upper surface of the lower electrode 510 and may be wider than the lower electrode 510.

An upper electrode 530 may be formed on the dielectric layer 520. The upper electrode 530 may include a first upper electrode 531 and a second upper electrode 533. The first upper electrode 531 may be aligned in a side profile of the dielectric layer 520, and the second upper electrode 533 may be formed to contact an upper surface of the first upper electrode 531. As shown in FIG. 3, the second upper electrode 533 may have a width narrower than that of the first upper electrode 531, but may not be limited thereto. The second upper electrode 533 may be formed to surround sides of the first upper electrode 531.

The first upper electrode 531 and the second upper electrode 533 may be formed of the same material or different materials. For example, each of the upper electrodes 531 and 533 may be formed of a single layer of Ti, TiN, TiW, Ta, TaN, W, WN, Pt, Ir, Ru, Rh, Os, Pd, Al and/or Cu and/or their deposition layer. Each of the upper electrodes 531 and 533 may not be limited to such material. The thickness of each upper electrode may be controlled depending on the semiconductor device. For example, the first upper electrode 531 may have a thickness of about 500 Å to about 1,500 Å while the second upper electrode 533 may have a thickness of about 1,000 Å to about 40,000 Å. An upper line 550 may be formed of the same conductive layer as that of the second upper electrode 533 in the upper insulating layer 600 formed on the lower insulating layer 500.

Referring to FIG. 4, although the upper surface of the upper insulating layer 600 is substantially even with those of the upper line 550 and the second upper electrode 533, it may not be limited to such a structure. For example, the upper surface of the upper insulating layer 600 may be higher than the upper line 550 and the second upper electrode 533.

Reference numerals 501 and 601 may denote etching stopper layers, which may be formed of a material having a relatively high etching selective ratio to the insulating layer. For example, if the insulating layer may be formed of an oxide material, the etching stopper layer may be formed of a nitride material.

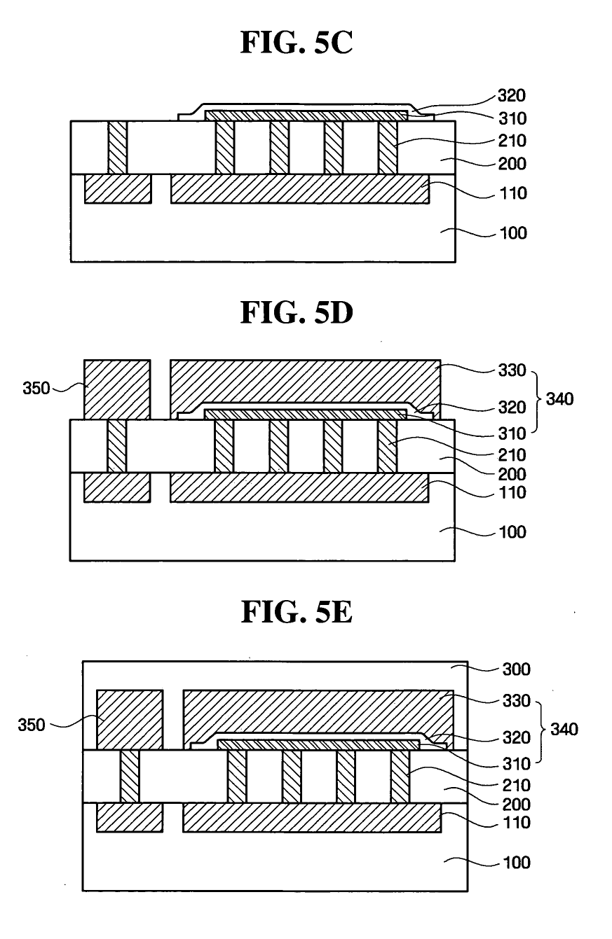

Hereinafter, a method of fabricating the aforementioned semiconductor device will be described. The process that may be formed by process steps widely known to those with ordinary skills in the art will be described in brief to reduce or prevent example embodiments from being construed ambiguously. A method of fabricating the semiconductor device shown in FIG. 1 will be described with reference to FIGS. 5A to 5E. Because elements of the semiconductor device are substantially the same as those of FIG. 1, their description will be omitted or will be described in brief.

As shown in FIG. 5A, the lower insulating layer 200 may be formed on the lower line 110. Vias 210 connected with the lower line 110 may be formed in the lower insulating layer 200 by a typical process. As shown in FIG. 5B, the lower electrode 310 of the capacitor may be formed on the lower insulating layer 200. The lower electrode 310 may be formed by forming a conductive layer for the lower electrode on the lower insulating layer 200 at a predetermined or given thickness and then patterning the conductive layer. Although not shown, the insulating spacer may additionally be formed on the sides of the lower electrode after the lower electrode is formed.

As shown in FIG. 5C, the dielectric layer 320 may be formed on the lower electrode 310. The dielectric layer 320 may be formed to cover the upper surface of the lower electrode 310 and may be wider than the lower electrode 310. The dielectric layer 320 may be formed to cover the sides of the lower electrode 310 along with the upper surface of the lower electrode 310 as shown in FIG. 5C. The dielectric layer 320 may extend onto the lower insulating layer 200 to adjoin the lower insulating layer 200.

The dielectric layer 320 may be formed by forming a dielectric layer on the lower insulating layer 200 to surround the upper surface and the sides of the lower electrode 310 and then patterning the dielectric layer. Because the dielectric layer 320 is patterned to have a width wider than that of the lower electrode 310, it may be possible to reduce or minimize damage of the lower electrode during an etching process of the dielectric layer. Because the lower electrode is completely formed before the dielectric layer is patterned, etching byproducts generated by etching of the lower electrode may not be attached to the sides of the dielectric layer 320, thereby avoiding short due to the etching byproducts. Subsequently, the upper electrode 330 may be formed as shown in FIG. 5D.

The upper electrode 330 may be formed to cover the upper surface and the sides of the dielectric layer 320. Because the upper electrode 330 is formed to have a predetermined or given margin from the sides of the dielectric layer 320 and the lower electrode 310, there may be no room to leave etching byproducts, which may be generated during the etching process for the upper electrode 330, on the sides of the dielectric layer 320. The dielectric layer or the lower electrode may not be damaged when the upper electrode is formed.

The upper line 350 may be formed of the same conductive layer as that of the upper electrode 330 when the upper electrode 330 is formed. The upper electrode 330 may be formed by forming the conductive layer for the upper electrode at a predetermined or given thickness and then patterning the conductive layer. The upper electrode 330 may not be limited to such a formation method. Subsequently, the upper insulating layer 300 may be formed to cover the upper surface of the upper electrode 330 as shown in FIG. 5E.

Although the upper insulating layer 300 is formed after the upper electrode 330 is formed, it may not be limited to such a formation method. In other words, the upper electrode 330 may be formed after the upper insulating layer 300 is formed. Although not shown, the upper electrode may be formed by a damascene process as follows. The upper insulating layer may be formed on the lower insulating layer in which the dielectric layer is formed. The upper insulating layer may then be patterned to form a trench in a region where the upper electrode is to be formed. A trench may be formed in a region where the upper line is formed. Subsequently, an exposed region may be buried by the known method using a metal material and then planarized, so that the upper electrode and the upper line are completed. The upper surface of the upper insulating layer may be formed to be substantially even with the upper surfaces of the upper electrode and the upper line.

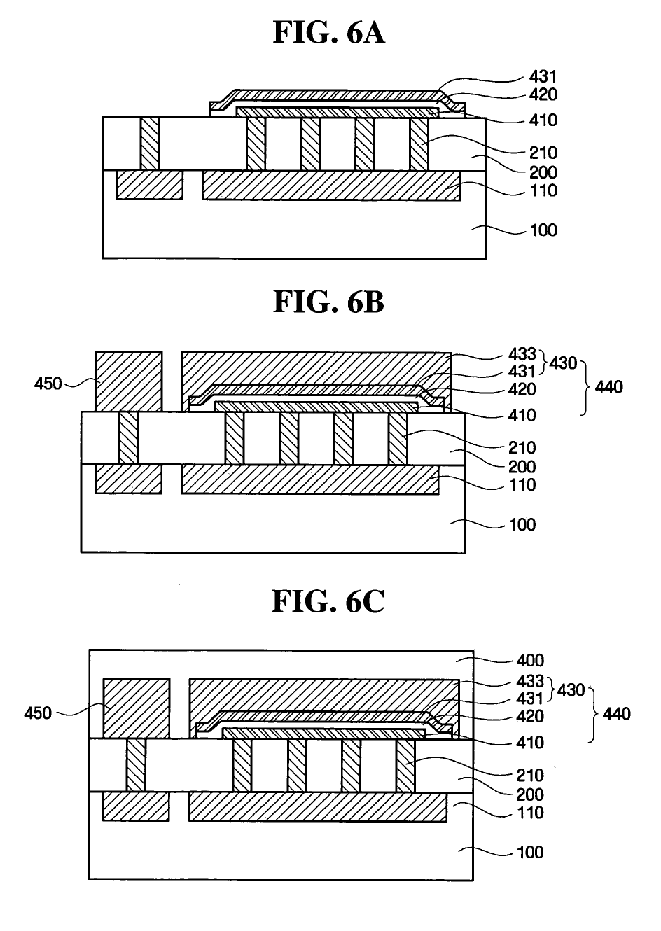

Although not shown, the semiconductor device may be completed by the process of additionally forming a line, the process of forming a passivation layer on a substrate, and the process of packaging the substrate. Such processes will be described in brief to reduce or prevent example embodiments from being construed ambiguously. Hereinafter, a method of fabricating the semiconductor device shown in FIG. 3 will be described with reference to FIGS. 6A to 6F. Because the process of forming the lower electrode, e.g., the process steps shown in FIGS. 5A and 5B may be applied to the method of fabricating the semiconductor device shown in FIG. 3, the later process will be described. Although not shown, the insulating spacer may additionally be formed on the sides of the lower electrode after the lower electrode is formed.

As shown in FIG. 6A, the first upper electrode 431, aligned in the side profile of the dielectric layer 420 while covering the upper surface of the dielectric layer 420, may be formed. For example, after the conductive layers for the dielectric layer and the first upper electrode are formed to cover the upper surface and the sides of the lower electrode 410, the conductive layers may be sequentially patterned to form the dielectric layer 420 and the first upper electrode 431, wherein the dielectric layer 420 covers the upper surface and the sides of the lower electrode 410, and the first upper electrode 431 may be formed on the dielectric layer 420 and aligned in the side profile of the dielectric layer 420. The dielectric layer 420 may be protected by the first upper electrode 431 during the etching process. Because the dielectric layer 420 is etched to have a width wider than that of the lower electrode 410 as described above, the etching byproducts of the lower electrode 410 may not be generated during the etching process of the dielectric layer as described above.

The dielectric layer 420 and the first upper electrode 430 may be formed together as described above. It may be advantageous in that the dielectric layer 420 and the first upper electrode 430 may be formed by one process. The dielectric layer 420 and the first upper electrode 430 may not be limited to such a formation process. The first upper electrode 431 may separately be formed after the dielectric layer 420 is formed. As shown in FIG. 6B, the second upper electrode 433 may be formed on the first upper electrode 431. The second upper electrode 433 may be formed to cover the upper surface of the first upper electrode 431 and surround the sides of the first upper electrode 431 and the dielectric layer 420, whereby the capacitor 440 is completed. Because the second upper electrode 433 is etched at a predetermined or given margin from the sides of the dielectric layer 420 and the first upper electrode 431, it may not be affected by the etching byproducts. It may be possible to reduce or prevent the dielectric layer from being undesirably etched and the lower electrode from being damaged. The second upper electrode may be formed by the damascene process. Subsequently, the upper insulating layer 400 may be formed as shown in FIG. 6C. As described above, the upper insulating layer 400 may be formed after the upper electrode is formed. Although not shown, the semiconductor device may be completed by the process of additionally forming a line, the process of forming a passivation layer on a substrate, and the process of packaging the substrate.

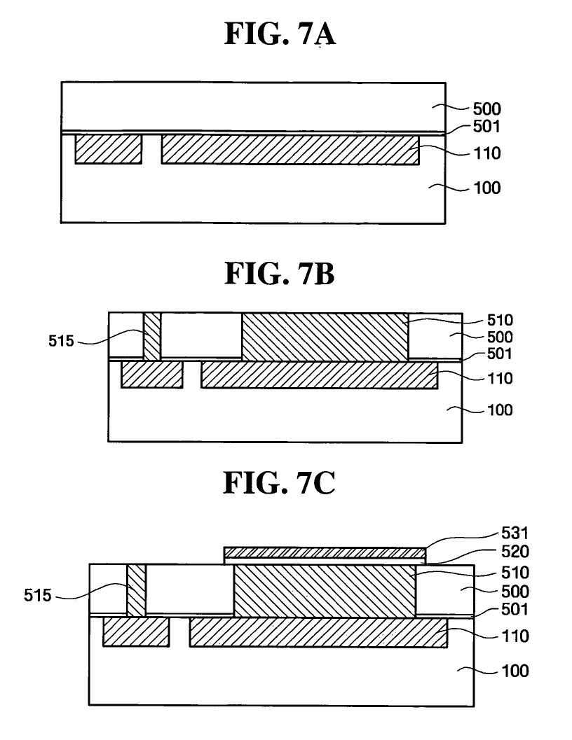

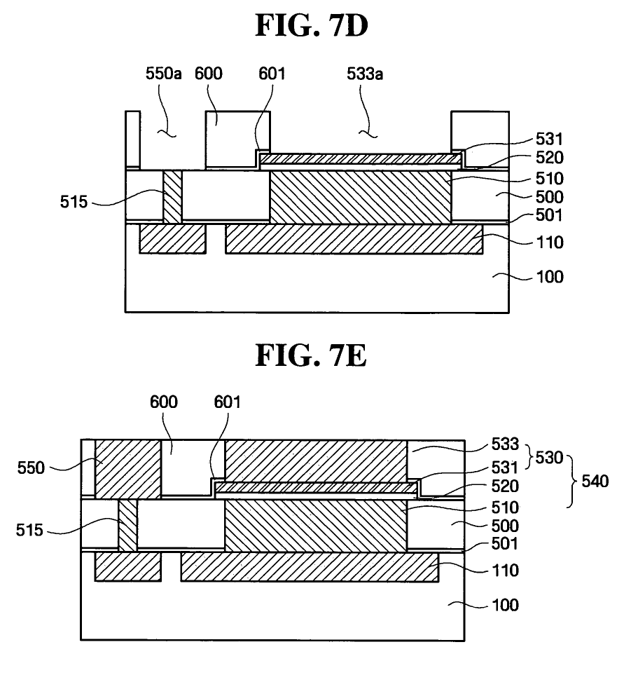

Hereinafter, a method of fabricating the semiconductor device shown in FIG. 4 will be described with reference to FIGS. 7A to 7E. Because elements of the semiconductor device shown in FIGS. 7A to 7E are substantially the same as those of FIG. 4, their description will be omitted or will be described in brief. Hereinafter, although a method of fabricating the semiconductor device shown in FIG. 4 will be described with using a damascene process, it may not be limited to such a formation method. As shown in FIG. 7A, the lower insulating layer 500 may be formed on the lower line 110. The etching stopper layer 501 may be formed before the lower insulating layer 500 is formed.

In FIG. 7B, the via 515 connected with the lower line 110 may be formed in the lower insulating layer 500. The lower electrode 510 may be formed of the same conductive layer as that of the via 515 in the lower insulating layer 500 along with the via 515. The via 515 may be formed by a damascene process. Subsequently, as shown in FIG. 7C, the dielectric layer 520 may be formed on the lower electrode 510. The dielectric layer 520 may be wider than the lower electrode 510. The first upper electrode 531, aligned in the side profile of the dielectric layer 520, may be formed on the dielectric layer 520.

For example, the dielectric layer 520 and the first upper electrode 531 may be formed as follows. The conductive layers for the dielectric layer and the first upper electrode may be sequentially formed on the lower insulating layer 500 in which the lower electrode 510 and the via 515 are formed. The dielectric layers are then sequentially patterned to form the dielectric layer 520 and the first upper electrode 531. In this way, the dielectric layer 520 and the first upper electrode 531 may be formed by the same process. It may be advantageous in that the dielectric layer 520 and the first upper electrode 531 may be formed by one process. The dielectric layer 520 and the first upper electrode 531 may not be limited to such a formation method. The first upper electrode 531 may separately be formed after the dielectric layer 520 is formed. The second upper electrode may be formed by the damascene process.

Referring to FIG. 7D, the etching stopper layer 601 may be formed to cover the upper surface of the lower insulating layer 500, the sides of the first upper electrode 531 and the dielectric layer 520, and the upper surface of the first upper electrode 531. The upper insulating layer 600 may then be formed on the etching stopper layer 601 and etched to respectively form a region 550a for the upper line and a region 533a for the upper electrode in the upper insulating layer 600. The first upper electrode 531 may protect the dielectric layer 533 from the etching process of the upper insulating layer 600. Subsequently, the upper line 550 and the second upper electrode 533 may be formed as shown in FIG. 7E. A barrier layer and a seed layer may further be formed in an inner wall and the bottom of the trench. The upper insulating layer 600 may be formed by a planarizing process (e.g., a CMP process) to have the same upper surface as those of the upper line 550 and the second upper electrode 533.

If the second upper electrode is not formed by the damascene process, the upper insulating layer may be formed after the second upper electrode is formed. Although not shown, the semiconductor device may be completed by the process of additionally forming a line, the process of forming a passivation layer on a substrate, and the process of packaging the substrate. As described above, the semiconductor device and the method of fabricating the same according to example embodiments have the following advantages. Because the capacitor may include the upper electrode and the dielectric layer wider than the lower electrode, the leakage of current between the upper electrode and the lower electrode may be reduced or minimized, thereby improving the reliability of the semiconductor device.

Example embodiments have been described for illustrative purposes, and those skilled in the art will appreciate that various modifications, additions and substitutions are possible without departing from the scope and spirit of the accompanying claims. Therefore, the scope of example embodiments should be defined by the appended claims and their legal equivalents.

What is claimed is:

1. A capacitor comprising:
a lower electrode;
a dielectric layer covering an upper surface of the lower electrode and having a width wider than that of the lower electrode; and
at least one upper electrode covering an upper surface and sides of the dielectric layer.

2. A semiconductor device comprising:
a lower insulating layer on a lower line;
the capacitor of claim 1, including the lower electrode in the lower insulating layer; and
an upper insulating layer on the lower insulating layer and encompassing the capacitor.

3. The semiconductor device of claim 2, wherein the upper insulating layer encompasses the dielectric layer and the at least one upper electrode.

4. The semiconductor device of claim 2, wherein the dielectric layer covers the upper surface and sides of the lower electrode.

5. The semiconductor device of claim 4, wherein the dielectric layer extends to the lower insulating layer to cover the sides of the lower electrode and adjoin the lower insulating layer.

6. The semiconductor device of claim 2, wherein a lower end of the at least one upper electrode partially adjoins the lower insulating layer.

7. The semiconductor device of claim 2, wherein the lower insulating layer includes a via connected to the lower electrode.

8. The semiconductor device of claim 7, wherein the via is connected to the lower line.

9. The semiconductor device of claim 8, wherein the lower electrode is formed of the same conductive layer as that of the via in the lower insulating layer.

10. The semiconductor device of claim 2, further comprising:
an upper line of the same conductive layer as that of the at least one upper electrode.

11. The capacitor of claim 1, further comprising:
an insulating spacer on the sides of the lower electrode.

12. The semiconductor device of claim 2, wherein the at least one upper electrode includes a first upper electrode on the dielectric layer and aligned in a side profile of the dielectric layer, and a second upper electrode on the first upper electrode to adjoin the first upper electrode and to encompass sides of the first upper electrode and the dielectric layer.

13. A semiconductor device comprising:
a lower insulating layer formed on a lower line;
a via formed in the lower insulating layer and connected with the lower line;
a capacitor including a lower electrode formed of the same conductive layer as that of the via in the lower insulating layer, a dielectric layer formed on the lower insulating layer to cover an upper surface of the lower electrode and having a width wider than that of the lower electrode, and at least one upper electrode composed of a first upper electrode formed on the dielectric layer and aligned in a side profile of the dielectric layer and a second upper electrode formed on the first upper electrode to adjoin the first upper electrode; and
an upper insulating layer formed on the lower insulating layer and including the dielectric layer and the at least one upper electrode therein.

14. The semiconductor device of claim 13, wherein the upper insulating layer is on the dielectric layer and the at least one upper electrode.

15. The semiconductor device of claim 13, wherein the at least one upper electrode includes a first upper electrode on the dielectric layer and aligned in a side profile of the dielectric layer, and a second upper electrode on the first upper electrode to adjoin the first upper electrode and to encompass sides of the first upper electrode and the dielectric layer.

16. The semiconductor device of claim 13, further comprising:
an upper line formed of the same conductive layer as that of the second upper electrode.

17. A method of fabricating a capacitor, comprising:
providing a lower electrode;
forming a dielectric layer covering an upper surface of the lower electrode and having a width wider than that of the lower electrode; and
forming at least one upper electrode covering an upper surface and sides of the dielectric layer.

18. A method of fabricating a semiconductor device, comprising:
forming a lower insulating layer on a lower line;
forming a capacitor according to claim 17, the lower electrode formed on the lower insulating layer; and
forming an upper insulating layer on the lower insulating layer before or after forming the upper electrode, the upper insulating layer encompassing the capacitor.

19. The method of claim 17, wherein forming the dielectric layer includes forming the dielectric layer to cover the upper surface and sides of the lower electrode.

20. The method of claim 19, wherein forming the dielectric layer includes forming the dielectric layer to extend to the lower insulating layer, cover the sides of the lower electrode and adjoin the lower insulating layer.

21. The method of claim 17, wherein a lower end of the at least one upper electrode partially adjoins the lower insulating layer.

22. The method of claim 17, further comprising:
forming an insulating spacer on the sides of the lower electrode before forming the dielectric layer.

23. The method of claim 17, wherein the lower insulating layer includes a via connected to the lower electrode.

24. The method of claim 23, wherein the via is connected to the lower line.

25. The method of claim 24, wherein the lower electrode is formed of the same conductive layer as that of the via in the lower insulating layer.

26. The method of claim 17, wherein forming the at least one upper electrode includes forming a first upper electrode along with the dielectric layer, which covers an upper surface of the dielectric layer and is aligned in a side profile of the dielectric layer, and forming a second upper electrode covering the first upper electrode and encompassing sides of the first upper electrode and the dielectric layer.

27. The method of claim 17, further comprising:
forming an upper line of the same conductive layer as that of the at least one upper electrode.

28. The method of claim 26, wherein forming the upper line includes forming the upper line of the same conductive layer as that of the second upper electrode.

29. The method of claim 26, wherein forming the upper insulating layer includes forming the upper insulating layer on the lower insulating layer before or after forming the second upper electrode.
